(19) United States
(12) Patent Application Publication
(10) Pub. No.: US 2024/0347685 A1
(43) Pub. Date: Oct. 17, 2024

(54) DISPLAY PANEL AND MANUFACTURING METHOD OF DISPLAY PANEL, AND DISPLAY APPARATUS

(71) Applicant: Tianma Advanced Display Technology Institute (Xiamen) Co., Ltd., Xiamen (CN)

(72) Inventors: Ning ZHANG, Xiamen (CN); Wei HE, Xiamen (CN); Xiu LIU, Xiamen (CN); Yangui FENG, Xiamen (CN); Xiao LI, Xiamen (CN)

(21) Appl. No.: 18/755,739

(22) Filed: Jun. 27, 2024

(30) Foreign Application Priority Data
Feb. 28, 2024 (CN) 202410223510.9

(51) Int. Cl. H01L 33/62; H01L 25/16

(52) U.S. Cl. CPC H01L 33/62; H01L 25/167; H01L 2933/0066

(57) ABSTRACT

A display panel, a method for manufacturing the display panel, and a display apparatus are provided. The display panel includes: a driving backboard including a substrate, a functional circuit and a first electrode electrically connected with the functional circuit; a connection structure located at a side of the driving backboard, the connection structure includes a first connection portion, and the first connection portion includes a first base material and a first connection metal. The first base material is not in contact with the first electrode, the first connection metal is at least partially located on a surface of the first base material away from the substrate, and the first connection metal is electrically connected to the first electrode.

### CROSS-REFERENCE TO RELATED APPLICATIONS

The present disclosure claims priority to Chinese Patent Application No. 202410223510.9, filed on Feb. 28, 2024, the content of which is incorporated herein by reference in its entirety.

### TECHNICAL FIELD

The present disclosure relates to the field of display technologies, and in particular, to a display panel, a manufacturing method of the display panel, and a display apparatus.

### BACKGROUND

A display panel includes a driving backboard and a connection metal that is provided at a side of the driving backboard. The connection metal is configured to being well connected with structures such as light-emitting devices.

In the related art, the connection metal is usually formed by a wet chemical plating process. In the wet chemical plating process, a conductive base material is formed at a side of the driving backplane, and then a metal is reduced on a surface of the conductive base material by using a chemical plating solution to form a metal plating layer which serves as the connection metal.

However, in an actual plating process, a portion of the conductive base material is prone to skip plating, resulting in the inability to plate metal on the surface of the conductive base material, thereby adversely affecting performance and yield of the display panel.

### SUMMARY

In a first aspect, embodiments of the present disclosure provide a display panel. The display panel includes a driving backplane and a connection structure. The driving backplane includes a substrate, a functional circuit and a first electrode electrically connected to the functional circuit. The connection structure is provided at a side of the driving backplane and comprising a first connection portion. The first connection portion includes a first base material and a first connection metal. The first base material is not in contact with the first electrode. The first connection metal is at least partially located on a surface of the first base material away from the substrate. The first connection metal is electrically connected to the first electrode.

In a second aspect, embodiments of the present disclosure provide a method for manufacturing a display panel. The display panel includes a driving backplane and a connection structure. The driving backplane includes a substrate, a functional circuit and a first electrode electrically connected to the functional circuit. The connection structure is provided at a side of the driving backplane and comprising a first connection portion. The first connection portion includes a first base material and a first connection metal. The first base material is not in contact with the first electrode. The first connection metal is at least partially located on a surface of the first base material away from the substrate. The first connection metal is electrically connected to the first electrode. The method includes: forming a driving backplane and a connection structure, wherein the driving backplane comprises a substrate, a functional circuit and a first electrode electrically connected to the functional circuit; the connection structure is located at a side of the driving backplane and comprises a first connection portion. Forming the first connection portion comprises: forming a first base material, wherein the first base material is not in contact with the first electrode; and forming a first connection metal on a surface of the first base material by using a chemical plating process, wherein the first connection metal is electrically connected to the first electrode.

In a third aspect, embodiments of the present disclosure provide a display apparatus including a display panel. The display panel includes a driving backplane and a connection structure. The driving backplane includes a substrate, a functional circuit and a first electrode electrically connected to the functional circuit. The connection structure is provided at a side of the driving backplane and comprising a first connection portion. The first connection portion includes a first base material and a first connection metal. The first base material is not in contact with the first electrode. The first connection metal is at least partially located on a surface of the first base material away from the substrate. The first connection metal is electrically connected to the first electrode.

### BRIEF DESCRIPTION OF DRAWINGS

In order to more clearly explain the embodiments of the present disclosure, the drawings to be used in the description of the embodiments will be briefly described below. The drawings in the following description are some embodiments of the present disclosure. For those skilled in the art, other drawings may further be obtained based on these drawings.

FIG. 1 is a manufacturing process flow diagram of a display panel in the related art;

FIG. 2 is a structural schematic diagram of a display panel in the related art;

FIG. 3 is another structural schematic diagram of a display panel in the related art;

FIG. 4 is a structural schematic diagram of a display panel according to an embodiment of the present disclosure;

FIG. 5 is a structural schematic diagram of a first connection metal according to an embodiment of the present disclosure;

FIG. 6 is a structural schematic diagram of a first connection metal according to another embodiment of the present disclosure;

FIG. 7 is a structural schematic diagram of a display panel according to another embodiment of the present disclosure;

FIG. 8 is a structural schematic diagram of a display panel according to another embodiment of the present disclosure;

FIG. 9 is a structural schematic diagram of a display panel according to another embodiment of the present disclosure;

FIG. 10 is a top view of a display panel according to an embodiment of the present disclosure;

FIG. 11 is a structural schematic diagram of a display panel according to another embodiment of the present disclosure;

FIG. 12 is a structural schematic diagram of a display panel according to another embodiment of the present disclosure;

FIG. 13 is a structural schematic diagram of a display panel according to another embodiment of the present disclosure;

FIG. 14 is a structural schematic diagram of a display panel according to another embodiment of the present disclosure;

FIG. 15 is a structural schematic diagram of a display panel according to another embodiment of the present disclosure;

FIG. 16 is a structural schematic diagram of a display panel according to another embodiment of the present disclosure;

FIG. 17 is a structural schematic diagram of a display panel according to another embodiment of the present disclosure;

FIG. 18 is a structural schematic diagram of a display panel according to another embodiment of the present disclosure;

FIG. 19 is a structural schematic diagram of a display panel according to another embodiment of the present disclosure;

FIG. 20 is a structural schematic diagram of a display panel according to another embodiment of the present disclosure;

FIG. 21 is a structural schematic diagram of a display panel according to another embodiment of the present disclosure;

FIG. 22 is a structural schematic diagram of a display panel according to another embodiment of the present disclosure.

FIG. 23 is a top view of a display panel according to another embodiment of the present disclosure;

FIG. 24 is a top view of a display panel according to another embodiment of the present disclosure; and

FIG. 25 is a top view of a display panel according to another embodiment of the present disclosure;

FIG. 26 is a structural schematic diagram of a display panel according to another embodiment of the present disclosure;

FIG. 27 is a structural schematic diagram of a display panel according to an embodiment of the present disclosure;

FIG. 28 is a structural schematic diagram of a display panel according to another embodiment of the present disclosure;

FIG. 29 is a top view of a display panel according to another embodiment of the present disclosure;

FIG. 30 is a structural schematic diagram of a display panel according to another embodiment of the present disclosure;

FIG. 31 is a top view of a display panel according to another embodiment of the present disclosure;

FIG. 32 is a structural schematic diagram of a display panel according to an embodiment of the present disclosure;

FIG. 33 is a structural schematic diagram of a display panel according to another embodiment of the present disclosure;

FIG. 34 is a structural schematic diagram of a display panel according to another embodiment of the present disclosure;

FIG. 35 is a top view of a display panel according to another embodiment of the present disclosure;

FIG. 36 is a process flow diagram of a display panel according to an embodiment of the present disclosure;

FIG. 37 is a process flow diagram of a display panel according to another embodiment of the present disclosure;

FIG. 38 is a process flow diagram of a display panel according to another embodiment of the present disclosure;

FIG. 39 is a process flow diagram of a display panel according to another embodiment of the present disclosure;

FIG. 40 is a process flow diagram of a display panel according to another embodiment of the present disclosure;

FIG. 41 is a process flow diagram of a display panel according to another embodiment of the present disclosure; and

FIG. 42 is a structural schematic diagram of a display apparatus according to an embodiment of the present disclosure.

### DESCRIPTION OF EMBODIMENTS

In order to better understand technical solutions of the present disclosure, the embodiments of the present disclosure are described in details referring to the drawings.

It should be clear that the described embodiments are merely part of the embodiments of the present disclosure rather than all of the embodiments. All other embodiments obtained by those skilled in the art without paying creative labor shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiments of the present disclosure and the attached claims are also intended to include plural forms thereof, unless noted otherwise.

It should be understood that the term “and/or” used in the context of the present disclosure is to describe a correlation relation of related objects, indicating that there may be three relations, e.g., A and/or B may indicate only A, both A and B, and only B. In addition, the symbol “/” in the context generally indicates that the relation between the objects in front and at the back of “/” is an “or” relationship.

As described in the background, at present, the connection metal is usually formed by a wet chemical plating process. FIG. 1 is a manufacturing process flow diagram of a display panel in the related art. When the connection metal is formed, as shown in FIG. 1, firstly, a conductive base material 102, such as a copper base material, is formed on a side of a driving backplane 101. The conductive base material 102 is located on a surface of an output electrode 103 in the driving backplane 101, and is in contact connection with the output electrode 103. Then, the metal is reduced on the surface of the conductive base material 102 by using a plating solution to form a metal plating layer, where the metal plating layer is a connection metal 104.

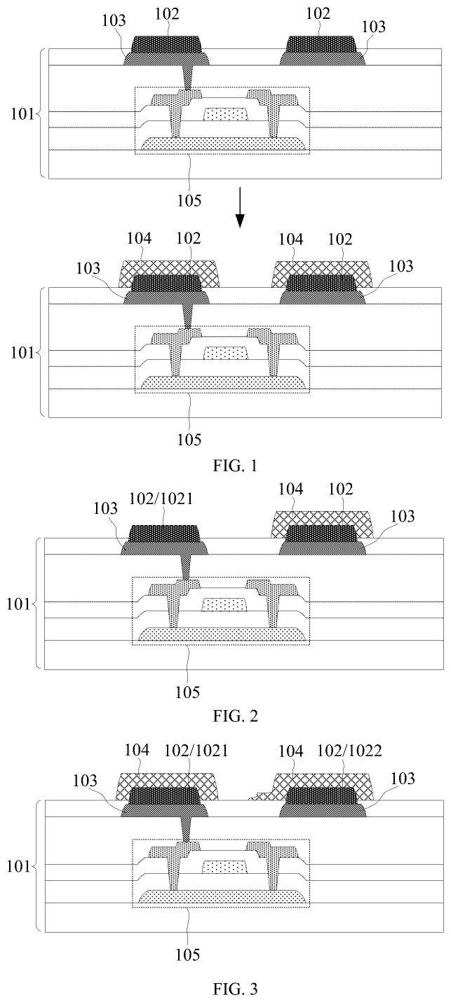

However, the inventors have found that the output electrode 103 connected to a portion of the conductive base material 102 may be further connected to a functional circuit 105, resulting in a smaller specific surface area (plated area/total area of non-plated circuits connected internally) of the portion of the conductive base material 102. When the connection metal 104 is subsequently formed, electrons generated on the surface of the portion of the conductive base material 102 by catalytic self-decomposition of the reducing agent in the chemical plating solution are easily adsorbed by the conductive base material 102 to migrate to the functional circuit 105, resulting in a decrease in the plating efficiency of the portion of the conductive base material 102. FIG. 2 is a structural schematic diagram of a display panel in the related art. As shown in FIG. 2, a portion of a conductive base material 1021 may undergo skip plating, causing a surface of the conductive base material 1021 to fail in forming the connection metal 104.

To address the above issues, in one embodiment, as shown in FIG. 3 which is another structural schematic diagram of the display panel in the related art, the concentration of active components in the chemical plating solution can be increased, so as to forcibly plate the connection metal 104 on these conductive base materials 1021 with smaller specific surface areas. However, for other conductive base materials 1022 that are not connected to the functional circuit 105 and have a larger specific surface area, they could have been normally plated. However, by increasing the concentration of the active component in the chemical plating solution, the areas near these conductive base materials 1022 that should not have been plated will be plated with metal due to uncontrolled activation, resulting in infiltration of the conductive base materials 1022, thereby increasing the risk of short circuit between the upper connection metal 104 and other structures.

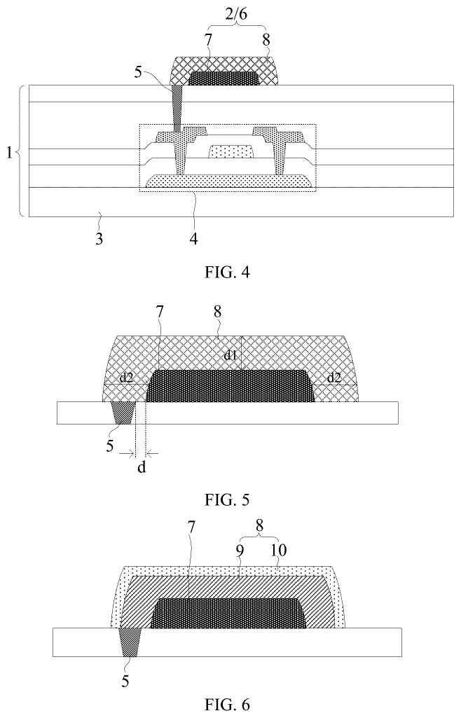

In this regard, an embodiment of the present disclosure provides a display panel, as shown in FIG. 4, which is a structural schematic diagram of a display panel according to an embodiment of the present disclosure, and the display panel includes a driving backplane 1 and a connection structure 2 located on a side of the driving backplane 1.

The driving backplane 1 includes a substrate 3, a functional circuit 4, and a first electrode 5. The first electrode 5 is electrically connected to the functional circuit 4.

The connection structure 2 includes a first connection portion 6. The first connection portion 6 includes a first base material 7 and a first connection metal 8. The first base material 7 is not in contact with the first electrode 5. The first connection metal 8 is at least partially located on a surface of the first base material 7 away from the substrate 3, and the first connection metal 8 is electrically connected to the first electrode 5.

In an embodiment of the present disclosure, the first base material 7 is a conductive base material 102, e.g., a copper base material. The first connection metal 8 is formed by a chemical plating process. After the first base material 7 is formed, the driving backplane 1 is placed in the chemical plating solution, and solvents such as a main salt and a reducing agent in the chemical plating solution react to reduce a metal on the surface of the first base material 7, thereby forming a metal plating layer on the surface of the first base material 7, that is, the first connection metal 8 is formed.

In an embodiment of the present disclosure, the relative position relationship between the first base material 7 and the first electrode 5 is adjusted. After the first base material 7 is formed, by ensuring that the first base material 7 and the first electrode 5 are not in contact with each other, the first base material 7 and the functional circuit 4 can be in a disconnection state, and the first base material 7 is an island electrode, effectively increasing the specific surface area of the first base material 7. The specific surface area of the base material refers to a ratio of a plated area of the base material to an area of the non-plated structure connected to the base material. Subsequently, when forming the first connection metal 8, electrons on the surface of the first base material 7 generated by catalytic self-decomposition of the chemical plating solution cannot be adsorbed by the first base material 7 to migrate into the functional circuit, allowing the chemical plating solution to normally reduce metal on the surface of the first base material 7 to form stable first connection metal 8, thereby avoiding skip plating of the first base material 7.

Different from the related art, although the first base material 7 in the present disclosure is not in direct contact with the first electrode 5, the metal has a characteristic of isotropic growth in the chemical plating process. Therefore, the first connection metal 8 not only grows upward on the top surface of the first base material 7, but also expand laterally outward simultaneously, and the laterally expanded first connection metal 8 may be electrically connected to the first electrode 5 on a side of the first base material 7, thereby achieving electrical connection between the first connection metal 8 and the functional circuit 4 inside the driving backplane 1.

In addition, compared to methods that improve the skip plating by increasing the concentration of active components in the plating solution, the technical solution provided by the embodiments of the present disclosure can selectively address the issue of skip plating in a portion of conductive base material without diffusion plating of other conductive base materials, resulting in a better improvement effect.

In the embodiments of the present disclosure, the first connection metal 8 is formed by the chemical plating process, rather than by an etching process. There are some differences in the connection metal formed at the surface of the conductive base material 102 by two different processes.

On the one hand, the metal in the chemical plating process has the characteristic of isotropic growth. The metal not only grows upwards on the top surface of the conductive base material 102, but also expand laterally outward simultaneously, resulting in the final shape of the connection metal extending from the shape of the first base material. FIG. 5 is a structural schematic diagram of the first connection metal 8 according to an embodiment of the present disclosure. In an embodiment of the present disclosure, as shown in FIG. 5, the first connection metal 8 covers the first base material 7, and the thickness of the portion of the first connection metal 8 growing upward from the top surface of the first base material 7 is consistent with the thickness of the portion of the first connection metal 8 grown laterally outward on each side of the first base material 7. A distance between a surface of the first connection metal 8 away from the substrate 3 and a surface of the first base material 7 away from the substrate 3 is defined as d1, and a distance between a side surface of the first connection metal 8 and a side surface of the first base material 7 adjacent to the side surface of the first connection metal 8 is defined as d2, where d1=d2.

However, the connection metal formed by the etching process is difficult to have the above structural characteristics. In the etching process for forming the connection metal, a whole layer of metal material needs to be deposited first, and then the metal material is etched to form a specific pattern. However, due to a certain angle between the side surface and the top surface of the conductive base material, the metal material at the side surface of the conductive base material is thinner than the metal material at the top surface of the substrate after the whole layer of metal material is deposited, thereby resulting in a difference in thickness of the connection metal between the side surface and the top surface of the substrate.

On the other hand, in the chemical plating process, the metal plating layer formed on the surface of the substrate after the reaction of the reducing agent with the main salt in the chemical plating solution is an alloy plating layer. For example, when the reducing agent in the plating solution includes phosphate, and the main salt includes nickel salt, the reducing agent reacts with the main salt to form a nickel-phosphorus alloy plating layer. FIG. 6 is a structural schematic diagram of a first connection metal 8 according to another embodiment of the present disclosure. As shown in FIG. 6, the first connection metal 8 includes a first metal sub-layer 9. The first metal sub-layer 9 is at least partially located on a surface of the first base material 7 away from the substrate 3, and includes an alloy.

In contrast, the metal layer formed by the etching process generally only includes a single metal material. At present, a layer including the alloy is difficult to be directly formed on the surface of the base material through the etching process.

On the other hand, in a chemical plating process for forming the connection metal, another plating layer may be formed on the surface of the alloy plating layer in one plating process by selecting a displacement-type chemical solution. For example, a displacement-type gold plating solution may be selected to form a gold plating layer on the surface of the nickel-phosphorus alloy plating layer, and the gold plating layer can make the connection metal achieve a better anti-oxidation effect. Referring to FIG. 6 again, the first connection metal 8 may further include a second metal sub-layer 10 located on a side of the first metal sub-layer 9 away from the first base material 7, e.g., the second metal sub-layer 10 covers the first metal sub-layer 9.

However, if the etching process is desired to form the connection metal with two metal sub-layers, the two metal sub-layers can only be formed separately through two etching processes, and cannot be formed by one etching process. In addition, if the etching process is desired to form gold layers, a whole layer of gold material needs to be deposited first, and then other gold materials except the pattern need to be removed, resulting in high costs, and thus low feasibility. Therefore, etching methods are generally not used to form the gold layers, and consequently, the etching processes are not adopted to form the connection metal including the gold layers.

In summary, the first connection metal 10 in the embodiments of the present disclosure may have structural features that metal formed by etching is difficult to have.

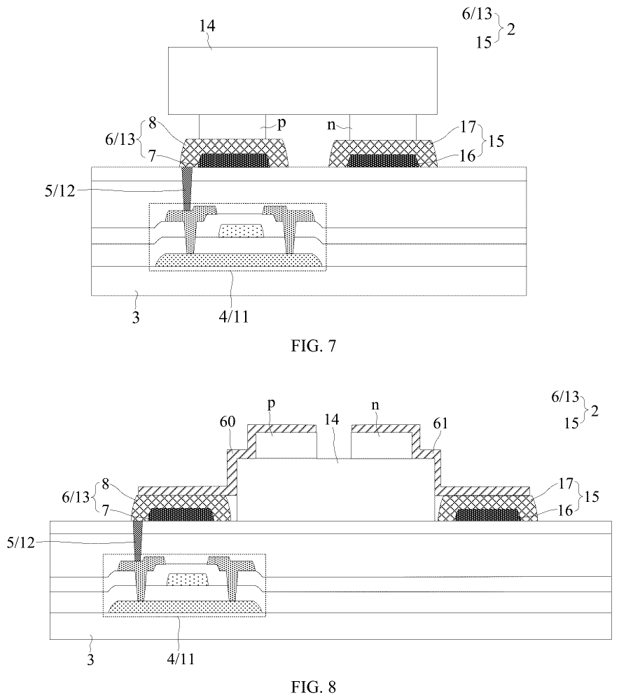

In an embodiment of the present disclosure, at least a portion of the first connection portion 6 may be configured to connect the light-emitting device. FIG. 7 is a structural schematic diagram of a display panel according to another embodiment of the present disclosure. As shown in FIG. 7, the functional circuit 4 includes a pixel circuit 11, and the first electrode 5 includes a first sub-electrode 12 electrically connected to the pixel circuit 11. The first connection portion 6 includes a type-I connection portion 13 electrically connected to the light-emitting device 14, e.g., the type-I connection portion 13 is electrically connected to a positive electrode p of the light-emitting device 14. In the type-I connection portion 13, the first base material 7 is not in contact with the first sub-electrode 12, and the first connection metal 8 is electrically connected to the first sub-electrode 12.

In addition, the connection structure 2 further includes a second connection portion 15, and at least a portion of the second connection portion 15 is electrically connected to the light-emitting device 14, e.g., at least a portion of the second connection portion 15 is electrically connected to a negative electrode n of the light-emitting device 14. The second connection portion 15 includes a second base material 16 and a second connection metal 17.

The second connection metal 17 is at least provided at a side of the second base material 16 away from the substrate 3. The second base material 16 and the first base material 7 are formed by a same process. The second connection metal 17 and the first connection metal 8 are formed by a same process.

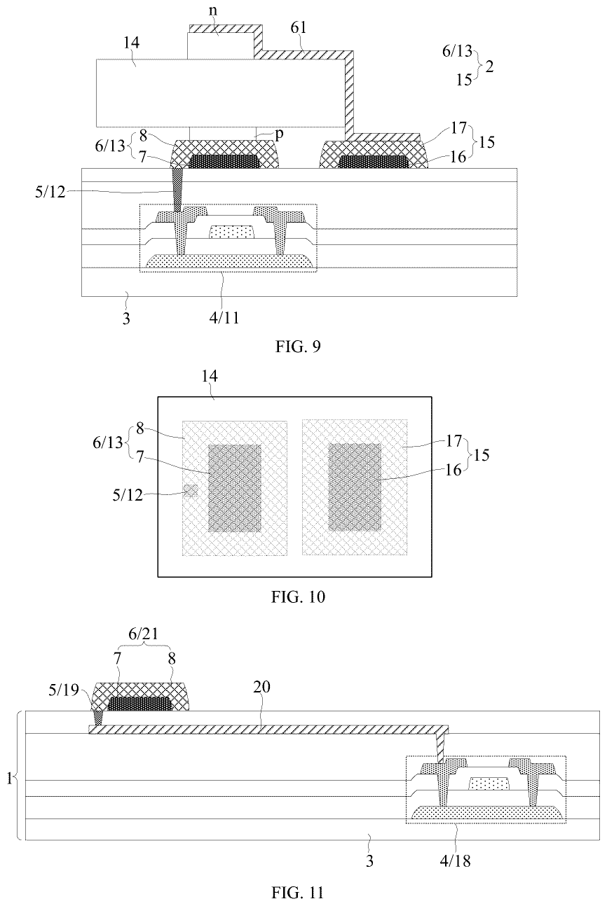

In an embodiment of the present disclosure, the light-emitting device 14 may be a light-emitting diode LED, such as a mini LED or a Micro LED. Moreover, the light-emitting device 14 may be a reverse-mounted LED as shown in FIG. 7. The positive electrode p and the negative electrode n of the light-emitting device 14 are located at a side adjacent to the driving backplane 1. The positive electrode p of the light-emitting device 14 is bonded to the type-I connection portion 13, and the negative electrode n is bonded to the second connection portion 15. FIG. 8 is a structural schematic diagram of the display panel according to an embodiment of the present disclosure. In an embodiment of the present disclosure, as shown in FIG. 8, the light-emitting device 14 may also be a forward-mounted LED. The positive electrode p and the negative electrode n of the light-emitting device 14 are located at a side away from the driving backplane 1. The positive electrode p of the light-emitting device 14 is electrically connected to the type-I connection portion 13 through the first connection line 60. The negative electrode n of the light-emitting device 14 is electrically connected to the second connection portion 15 through the second connection line 61. FIG. 9 is a structural schematic diagram of a display panel according to another embodiment of the present disclosure. As shown in FIG. 9, the light-emitting device 14 may also be a vertical LED. The positive electrode p of the light-emitting device 14 is located at a side adjacent to the driving backplane 1 and bonded to the type-I connection portion 13. The negative electrode n of the light-emitting device 14 is located at a side away from the driving backplane 1 and electrically connected to the second connection portion 15 through the second connection line 61.

Based on the analysis above, it can be seen that, since the first base material 7 in the type-I connection portion 13 is not in contact with the first sub-electrode 12, this portion of the first base material 7 may have a larger specific surface area. In this way, the difference in the specific surface area between the first base material 7 and the second base material 16 is weakened, so that the plating efficiency of the first base material 7 and the second base material 16 tends to be consistent, stably forming the connection metal above the first base material 7 and the second base material 16, thereby improving the connection reliability between the light-emitting device 14 and the driving backplane 1.

FIG. 10 is a top view of a display panel according to an embodiment of the present disclosure. Further, as shown in FIG. 10, for the type-I connection portion 13, the second connection portion 15, and the first sub-electrode 12 electrically connected to the same light-emitting device 14, the first sub-electrode 12 may be arranged at a side of the first base material 7 in the type-I connection portion 13 away from the second connection portion 15, to prevent the first sub-electrode 12 from being short-circuited with the second connection metal 17.

In an embodiment of the present disclosure, at least a portion of the first connection portion may also serve as a driving structure such as a connection driving chip. FIG. 11 is a structural schematic diagram of a display panel according to another embodiment of the present disclosure. As shown in FIG. 11, the functional circuit 4 includes a first circuit 18, and the first electrode 5 includes a pin electrode 19 electrically connected to the first circuit 18 through a first signal line 20. The first connection portion 6 includes a type-II connection portion 21. In the type-II connection portion 21, the first base material 7 is not in contact with the pin electrode 19, and the first connection metal 8 is electrically connected to the pin electrode 19.

The pin electrode 19 may be located in a frame of the display panel, and the type-II connection portion 21 is configured to be electrically connected to the driving structure. A signal provided by the driving structure is transmitted to the first circuit 18 through the first signal line 20 to drive the first circuit 18 to work normally.

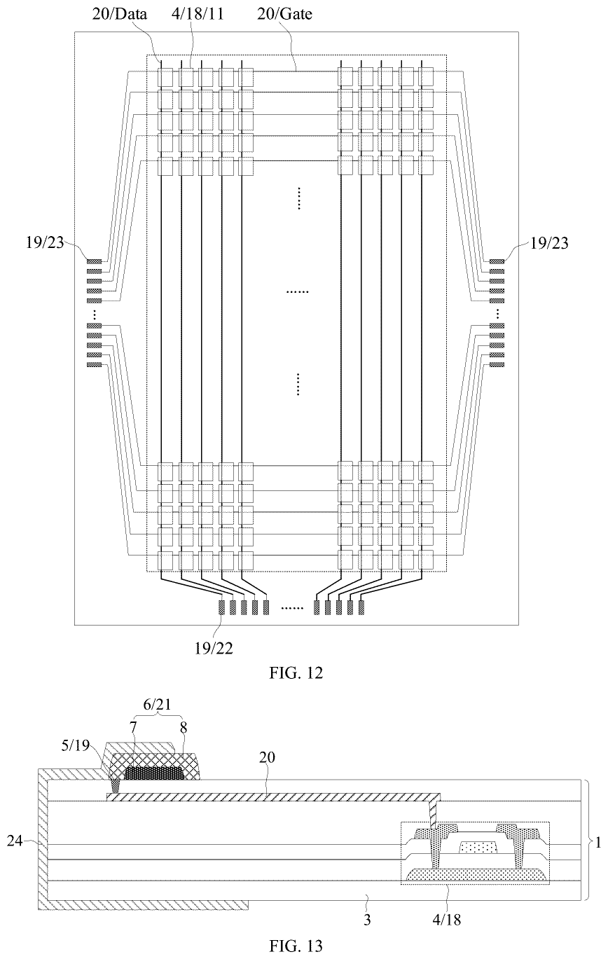

In an embodiment of the present disclosure, the first circuit 18 may include various circuits such as a pixel circuit 11, a shift register circuit, and an electrostatic protection circuit. FIG. 12 is a structural schematic diagram of a display panel according to another embodiment of the present disclosure. For example, as shown in FIG. 12, the first circuit 18 includes a pixel circuit 11, and the first signal line 20 includes a data line Data and/or a gate line Gate. The pin electrode 19 includes a first pin electrode 22 and/or a second pin electrode 23, and the first pin electrode 22 is electrically connected to the pixel circuit 11 through the data line Data and configured to transmit a data signal provided by a data driving chip to the pixel circuit 11. The second pin electrode 23 is electrically connected to the pixel circuit 11 through the gate line Gate and configured to transmit a gate signal provided by a gate driving chip to the pixel circuit 11. In an embodiment of the present disclosure, the first circuit 18 may include the shift register circuit, and correspondingly, the first signal line 20 may include signal lines such as a clock line and a frame start line.

It should be noted that the position of the frame where the pin electrode 19 is located is not limited in the present disclosure, and the pin electrode 19 may be located in at least one of the four frames on the upper, lower, left, and right sides. For example, referring to FIG. 12 again, for ease of wiring, the first pin electrode 22 may be located at the lower frame, and the second pin electrode 23 may be located at the left frame and/or the right frame.

Based on the analysis above, it can be seen that since the first base material 7 in the type-II connection portion 21 is not in contact with the pin electrode 19, this portion of the first base material 7 may have a larger specific surface area and a higher plating efficiency, stably forming a connection metal above the first base material 7, thereby improving the connection reliability between the driving structure and the driving backplane 1.

FIG. 13 is a structural schematic diagram of the display panel according to another embodiment of the present disclosure. Further, as shown in FIG. 13, the type-II connection portion 21 is further electrically connected to the lead-out wire 24, and the lead-out wire 24 extends from a side of the driving backplane 1 facing the type-II connection portion 21 to a side of the driving backplane 1 away from the type-II connection portion 21, so that the driving structure can be connected to the type-II connection portion 21 after being arranged at a back side of the driving backplane 1, without occupying a front frame space of the display panel, thereby optimizing a narrow frame design of the display panel.

In an embodiment of the present disclosure, the first connection metal 8 is directly electrically connected to the first electrode 5. Referring to FIG. 4 again, at least a portion of the first electrode 5 is exposed to the driving backplane 1, and the first connection metal 8 is in contact with the first electrode 5. That is, at least a portion of the surface of the first electrode 5 away from the substrate 3 is exposed and is not covered by other layers in the driving backplane 1, and this portion of the first connection metal 8 grown laterally outward will contact the exposed surface of the first electrode 5, enabling stable contact electrical connection between them.

In an embodiment of the present disclosure, the first connection metal 8 is indirectly electrically connected to the first electrode 5. FIG. 14 is a structural schematic diagram of a display panel according to another embodiment of the present disclosure. As shown in FIG. 14, the display panel further includes a protective base material 25. The protective base material 25 and the first base material 7 are in a same layer and spaced apart from each other. At least a portion of the first electrode 5 is exposed to the driving backplane 1. The protective base material 25 covers and contacts the exposed portion of the first electrode 5 and is further electrically connected to the first connection metal 8.

The first base material 7 is formed by the etching process. When forming the first base material 7, a whole layer of copper material needs to be deposited on the driving backplane 1, and then an etching solution is used to etch away the copper material that does not need to be retained. If the protective base material 25 is further provided above the first electrode 5, the copper material above the first electrode 5 needs to be retained, so that when the etching solution is used to etch the copper material, the etching solution can be prevented from contacting the first electrode 5 without contamination or corrosion to the first electrode 5.

Further, referring to FIG. 14 again, a distance between a surface of the first connection metal 8 on a side away from the substrate 3 and a surface of the first base material 7 on a side away from the substrate 3 is d1, and a distance h1 between the protective base material 25 and the first base material 7 is smaller than 2×d1.

Since the first connection metal 8 grows isotropically during formation, when the thickness of the portion of the first connection metal 8 growing upward from the top surface of the first base material 7 is d1, which means that the first connection metal 8 needs to expand laterally d1, and the third connection metal 26 formed on the surface of the protective base material 25 also needs to laterally expand d1. The distance between the protective base material 25 and the first base material 7 is set to be smaller than 2×d1, so that the first connection metal 8 is in contact with the third connection metal 26 to be connected together, thereby achieving that the first connection metal 8 can be electrically connected to the first electrode 5.

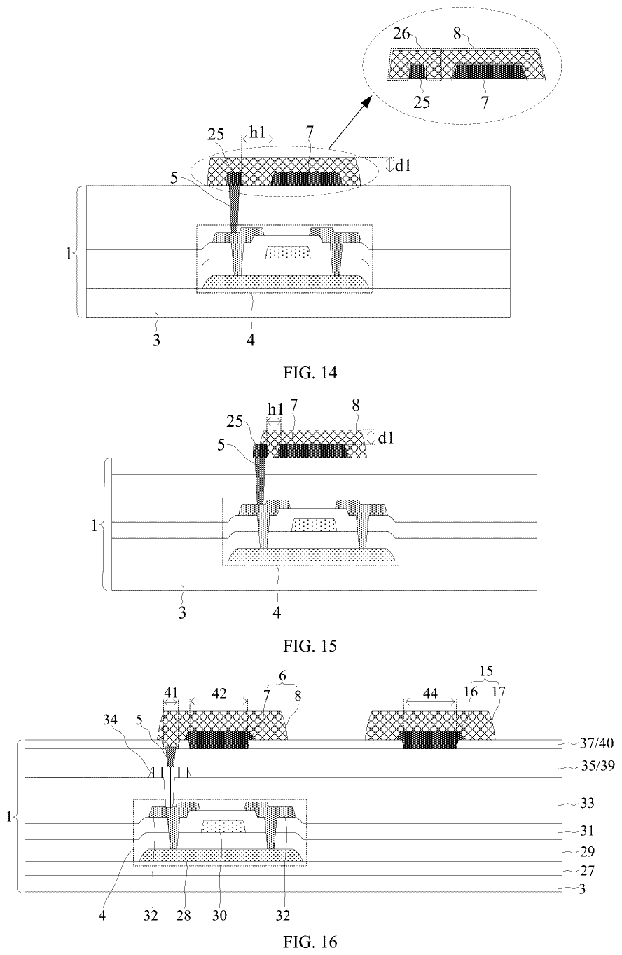

FIG. 15 is a structural schematic diagram of a display panel according to another embodiment of the present disclosure. Further, as shown in FIG. 15, the distance between the protective base material 25 and the first base material 7 may be set to be smaller than d1, so that even if skip plating occurs on the protective base material 25 due to the connection to the functional circuit 4, and a connection metal is not formed on a surface of the protective base material 25, so that the first connection metal 8 can contact the protective base material 25, thereby achieving that the first connection metal 8 is electrically connected to the first electrode 5.

In an embodiment of the present disclosure, referring to FIG. 4 again, there is a gap between the orthographic projection of the first base material 7 on the substrate 3 and the orthographic projection of the first electrode 5 on the substrate 3, which means that the positions of the two are staggered from each other, and do not overlap with each other, resulting in lower contact risk.

Further, referring to FIG. 5 again, the distance between the surface of the side of the first connection metal 8 away from the substrate 3 and the surface of the side of the first base material 7 away from the substrate 3 is d1, and the distance d between the orthographic projection of the first base material 7 on the substrate 3 and the orthographic projection of the first electrode 5 on the substrate 3 is smaller than d1, so that the first connection metal 8 grown laterally outward can overlap the first electrode 5, thereby achieving stable electrical connection between the first connection metal 8 and the first electrode 5.

Further, when designing the specific value of d mentioned above, if d is excessively small, the first base material 7 is excessively near the first electrode 5, leading to a contact risk. If d is excessively large, it is required that the first connection metal 8 laterally expands by a large thickness to achieve connection with the first output electrode. However, the excessive lateral expansion thickness of the first connection metal 8 means that the portion of the first connection metal 8 growing upward from the top surface of the first base material 7 is very thick, resulting in a large height of the first connection portion 6 and affecting the thickness of the module. Therefore, in the embodiments of the present disclosure, d may be set to: 1 μm≤d≤3 μm, so that a reasonable distance exists between the first base material 7 and the first electrode 5, thereby reducing the contact risk of the first base material 7 and the first electrode 5, and not imposing excessive requirements on the growth thickness of the first connection metal 8.

In a layer structure of the driving backplane 1, referring to FIG. 16 to FIG. 20, the driving backplane 1 includes a buffer layer 27, a semiconductor layer 28, a gate insulation layer 29, a first metal layer 30, an interlayer insulation layer 31, a second metal layer 32, a first planarization layer 33, a third metal layer 34, a second planarization layer 35, and a protective insulation layer 37 that are stacked on the substrate 3.

The semiconductor layer 28 is configured to form an active layer of a transistor, the first metal layer 30 is configured to form a gate electrode of the transistor, the second metal layer 32 is configured to form a first electrode and a second electrode of the transistor, and the third metal layer 34 is configured to form an auxiliary connection portion. For example, a portion of the auxiliary connection portion may be connected between the first electrode 5 and the transistor of the functional circuit 4.

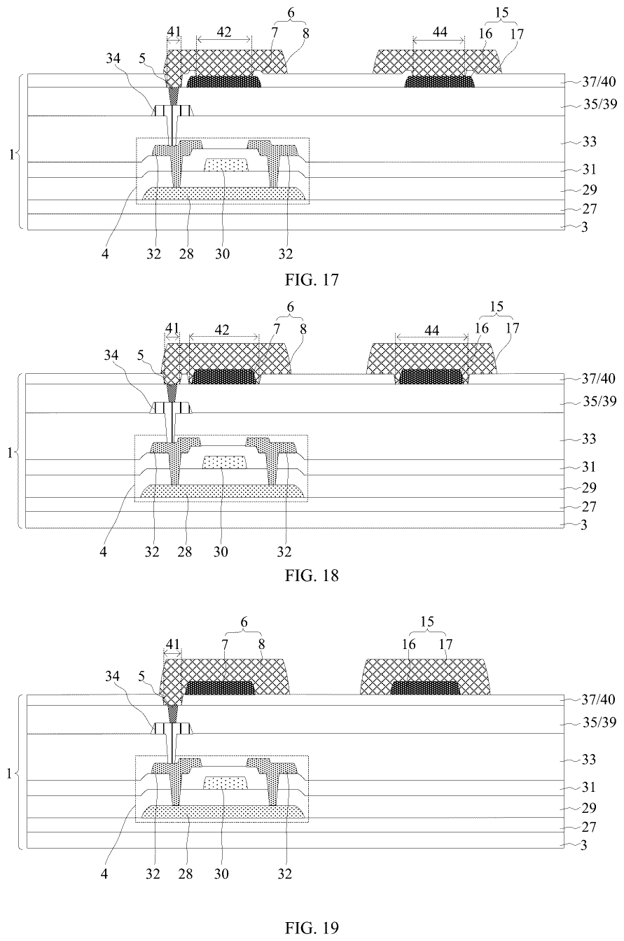

FIG. 16 is a structural schematic diagram of a display panel according to another embodiment of the present disclosure, FIG. 17 is a structural schematic diagram of a display panel according to another embodiment of the present disclosure, FIG. 18 is a structural schematic diagram of a display panel according to another embodiment of the present disclosure, and FIG. 19 is a structural schematic diagram of a display panel according to another embodiment of the present disclosure. In an embodiment of the present disclosure, as shown in FIG. 16 to FIG. 19, the first electrode 5 penetrates through the first insulation layer 39, and the second insulation layer 40 has a first aperture 41 exposing the first electrode 5.

In an embodiment of the present disclosure, the second insulation layer 40 may be understood as an insulation layer farthest away from the substrate 3 in the driving backplane 1. The second insulation layer 40 may be a protective insulation layer 37, e.g., including a silicon nitride material, to protect the functional circuit 4 inside the driving backplane 1 from being eroded by water and oxygen. The first insulation layer 39 may be a second planarization layer 35.

Referring to FIG. 16 to FIG. 18, the second insulation layer 40 further has a second aperture 42, and the first base material 7 is at least partially located at the second aperture 42.

In an embodiment of the present disclosure, referring to FIG. 19, the first base material 7 is located at a side of the second insulation layer 40 away from the substrate 3.

When the second insulation layer 40 has the second aperture 42, and the first base material 7 is at least partially located at the second aperture 42:

In one structure, referring to FIG. 16, the first base material 7 covers the second aperture 42, and a portion of the first base material 7 is located at a side of the second insulation layer 40 away from the substrate 3. Referring to FIG. 36, in this structure, the second insulation layer 40 needs to be formed first, and then the first base material 7 needs to be formed, so that the surface of the formed first base material 7 does not have the residue of the insulation material, facilitating the subsequent growth of the connection metal on the surface of the first base material 7. Moreover, no gap is left between the first base material 7 and the second insulation layer 40 at this time. When growing metal by using the plating solution, the plating solution can be prevented from penetrating into the driving backplane 1 through the second insulation layer 40.

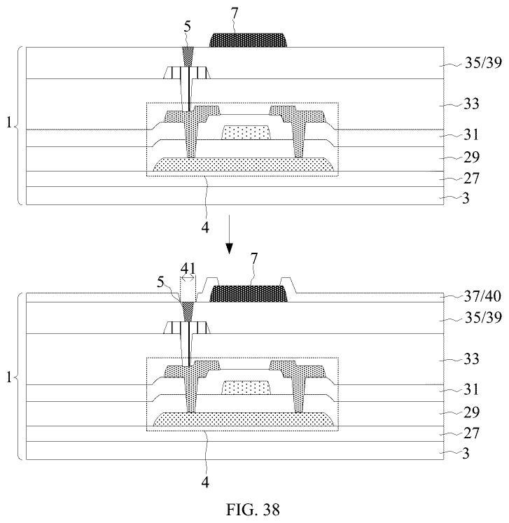

In an embodiment of the present disclosure, in another structure, referring to FIG. 17, the second aperture 42 exposes a portion of the first base material 7, and a portion of the second insulation layer 40 is hung above the first base material 7. Referring to FIG. 38, in this structure, the first base material 7 needs to be formed, and then the second insulation layer 40 needs to be formed. At this time, no gap is further left between the first base material 7 and the second insulation layer 40, which can prevent the plating solution from infiltrating into the interior of the driving backplane 1.

In an embodiment of the present disclosure, in another structure, referring to FIG. 18, the first base material 7 is entirely located in the second aperture 42. In this structure, the second insulation layer 40 may be formed first, and then the first base material 7 may be formed. In an embodiment of the present disclosure, the first base material 7 may be formed first, and then the second base material 16 may be formed.

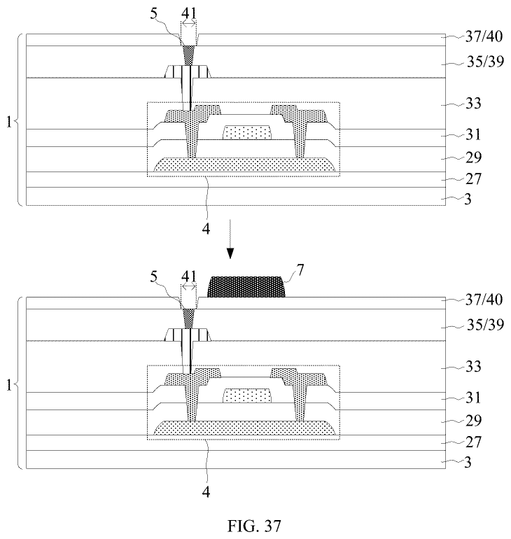

When the first base material 7 is located at a side of the second insulation layer 40 away from the substrate 3, in combination with FIG. 37, the second insulation layer 40 is formed first, and then the first base material 7 is formed. In this case, the second insulation layer 40 may not be provided with the second aperture 42, resulting in a larger coverage area of the second insulation layer 40 on the first insulation layer 39 and achieving better water and oxygen resistance effect.

Further, referring to FIG. 16 and FIG. 17 again, the first base material 7 is at least partially located in the second aperture 42, and the orthographic projection of the first base material 7 on the substrate 3 overlaps with the orthographic projection of the second insulation layer 40 on the substrate 3, preventing a gap from being left between the first base material 7 and the second insulation layer 40, and subsequently preventing the plating solution from infiltrating into the driving backplane 1 along the gap.

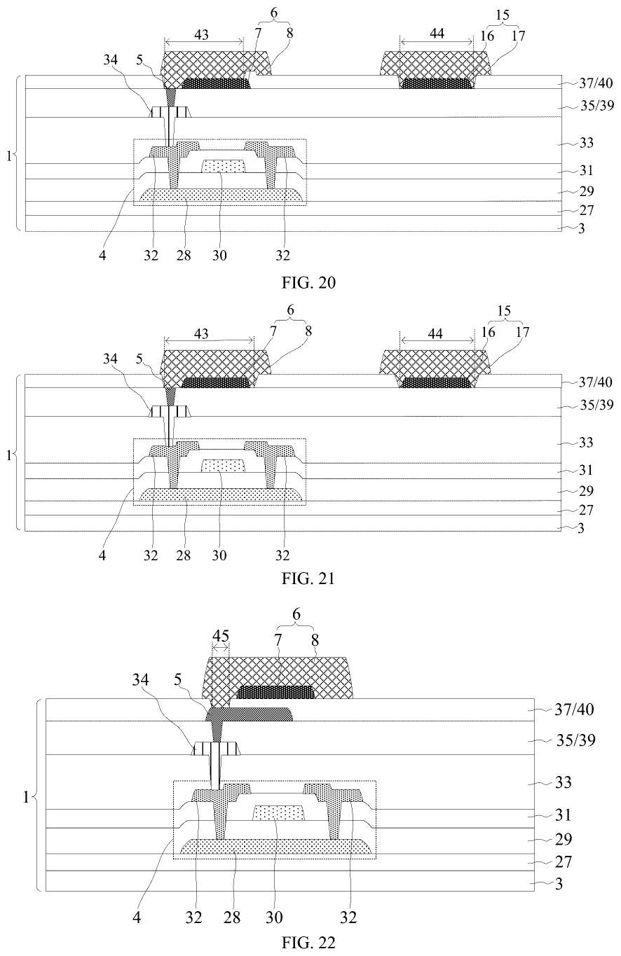

FIG. 20 is a structural schematic diagram of a display panel according to another embodiment of the present disclosure, and FIG. 21 is a structural schematic diagram of a display panel according to another embodiment of the present disclosure. In an embodiment of the present disclosure, as shown in FIG. 20 and FIG. 21, the driving backplane 1 includes a first insulation layer 39 and a second insulation layer 40. The first insulation layer 39 is located on a side of the functional circuit 4 away from substrate 3. The second insulation layer 40 is located on a side of the first insulation layer 39 away from substrate 3. The first electrode 5 penetrates through the first insulation layer 39.

The second insulation layer 40 includes a third aperture 43 exposing a first electrode 5 and simultaneously exposing at least a portion of the first base material 7 adjacent to the first electrode 5. For example, referring to FIG. 20, the third aperture 43 exposes the first electrode 5 and exposes a portion of the first base material 7, and an edge of the first base material 7 not adjacent to the first electrode 5 is covered by the second insulation layer 40 without leaving a gap with the second insulation layer 40, which can reduce the risk of inward infiltration of the plating solution along the gap. In an embodiment of the present disclosure, referring to FIG. 21, the third aperture 43 may expose all of the first electrode 5 and the first base material 7.

In this structure, the third aperture 43 has a larger area, which can expose the side of the first base material 7 adjacent to the first electrode 5. The second insulation layer 40 does not affect the lateral outward expansion of the metal on the side of the first base material 7, allowing the metal to normally expand and ensuring electrical connection between the first connection metal 8 and the first electrode 5 to a greater extent.

In an embodiment of the present disclosure, referring to FIG. 16 to FIG. 21 again, the connection structure 2 further includes a second connection portion 15, and the second connection portion 15 includes a second base material 16 and a second connection metal 17 at least partially located on a surface of the second base material 16 away from the substrate 3. A lower surface of the first base material 7 facing the substrate 3 and a lower surface of the second base material 16 facing the substrate 3 are in contact with a same insulation layer in the driving backplane 1.

For example, as shown in FIG. 16 to FIG. 18, the lower surface of the first base material 7 and the lower surface of the second base material 16 are both in contact with the first insulation layer 39. At this time, the second insulation layer 40 further includes a fifth aperture 44, and at least a portion of the second base material 16 is located in the fifth aperture 44. In an embodiment of the present disclosure, as shown in FIG. 19, the lower surface of the first base material 7 and the lower surface of the second base material 16 are both in contact with the second insulation layer 40.

The first base material 7 and the second base material 16 are located at the same insulation layer, so that the heights of the first base material 7 and the second base material 16 are consistent, thereby making the heights of the subsequently formed first connection metal 8 and second connection metal 17 be consistent. When the first connection portion 6 and the second connection portion 15 are bound to the light-emitting device 14, the stability of the light-emitting device 14 can be improved.

FIG. 22 is a structural schematic diagram of a display panel according to another embodiment of the present disclosure. In an embodiment of the present disclosure, as shown in FIG. 22, in a direction perpendicular to a plane of the substrate 3, the first electrode 5 overlaps with the first base material 7, and at least one insulation layer, for example, a second insulation layer 40, is sandwiched between the first electrode 5 and the first base material 7. The at least one insulation layer includes a fourth aperture 45, and the fourth aperture 45 exposes the first electrode 5 and does not overlap with the first base material 7. The first electrode 5 under this structure can still retain the original pattern without adjusting the pattern to avoid the first base material 7, so that the mask plate for forming the first electrode 5 does not need to be replaced, thereby saving costs.

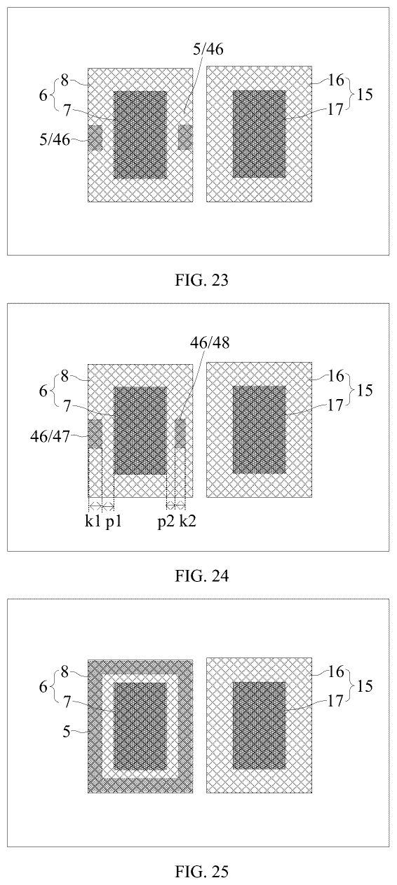

FIG. 23 is a top view of the display panel according to another embodiment of the present disclosure. In an embodiment of the present disclosure, as shown in FIG. 23, the first electrode 5 includes at least two sub-portions 46, and the at least two sub-portions 46 are located at different sides of the first base material 7, respectively. The at least two sub-portions 46 may communicate with each other or may be independent of each other. When at least two sub-portions 46 are independent of each other, each sub-portion 46 is connected to the first electrode 5.

The first electrode 5 under this structure is located at at least two sides of the first base material 7, and the first connection metal 8 may be electrically connected to the first electrode 5 in more directions, thereby improving connection reliability.

FIG. 24 is a top view of the display panel according to another embodiment of the present disclosure. Further, as shown in FIG. 24, the at least two sub-portions 46 include a first sub-portion 47 and a second sub-portion 48 that are located at opposite sides of the first base material 7.

The first sub-portion 47 has a first size k1 along an arrangement direction of the first sub-portion 47 and the first base material 7. The second sub-portion 48 has a second size k2 along an arrangement direction of the second sub-portion 48 and the first base material 7, and the first size k1 is different from the second size k2.

In an embodiment of the present disclosure, a first distance p1 exists between the orthographic projection of the first sub-portion 47 on the substrate 3 and the orthographic projection of the first base material 7 on the substrate 3, and a second distance p2 exists between the orthographic projection of the second sub-portion 48 on the substrate 3 and the orthographic projection of the first base material 7 on the substrate 3. The first distance p1 is greater than the second distance p2.

In the above arrangement, the size design of the sub-portions 46 at different sides of the first base material 7 and the distance design between the sub-portions 46 and the first base material 7 may be more flexible. For example, referring to FIG. 24, the second sub-portion 48 is located at a side of the first base material 7 adjacent to the second base material 16. At this time, the second size k2 of the second sub-portion 48 and/or the second distance p2 between the second sub-portion 48 and the first base material 7 may be designed smaller to prevent the second sub-portion 48 from being short-circuited with the second connection metal 17.

FIG. 25 is a top view of the display panel according to another embodiment of the present disclosure. In an embodiment of the present disclosure, in order to further improve the connection reliability between the first connection metal 8 and the first electrode 5, as shown in FIG. 25, the orthographic projection of the first electrode 5 on the substrate 3 may at least partially surround the orthographic projection of the first base material 7 on the substrate 3.

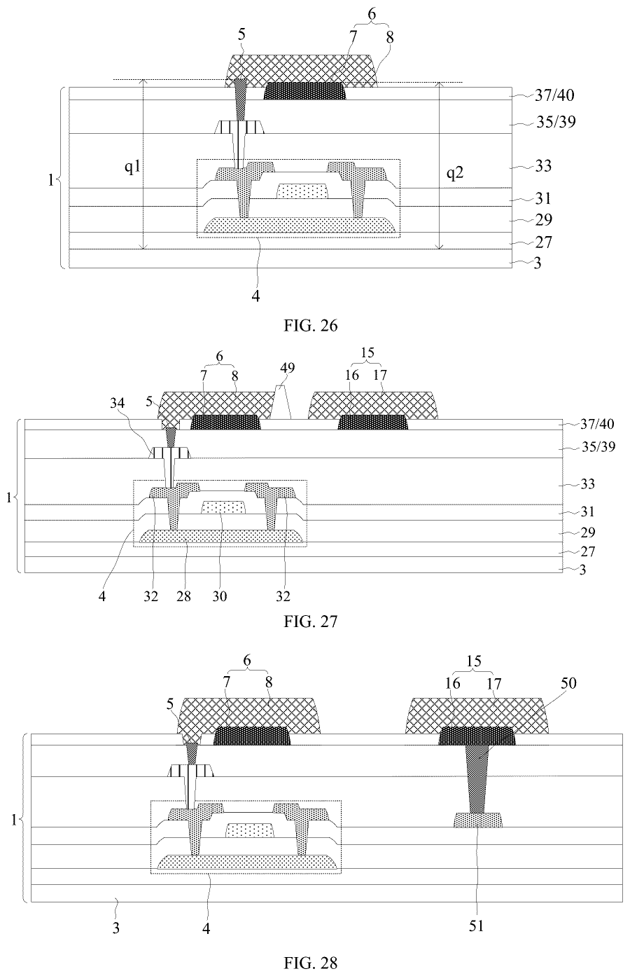

In an embodiment of the present disclosure, as shown in FIG. 26, FIG. 26 is a structural schematic diagram of a display panel according to another embodiment of the present disclosure. A distance q1 between an upper surface of a side of the first electrode 5 away from the substrate 3 and the substrate 3 is greater than a distance q2 between an upper surface of a side of the first base material 7 away from the substrate 3 and the substrate 3. In other words, the first electrode 5 protrudes from the second insulation layer 40, so that the first connection metal 8 is electrically connected to the first electrode 5 more easily.

FIG. 27 is a structural schematic diagram of a display panel according to another embodiment of the present disclosure. In an embodiment of the present disclosure, as shown in FIG. 27, the display panel further includes a dam 49. The dam 49 and the first electrode 5 are located at different sides of the first base material 7, respectively.

The dam 49 is arranged at a side of the first base material 7, and the lateral expansion growth of the metal on the side of the first base material 7 is blocked by using the dam 49, thereby reducing the lateral expansion degree of the metal on the side. For example, the first electrode 5 is located at a side of the first base material 7 away from the second base material 16, and the dam 49 is located at a side of the first base material 7 adjacent to the second base material 16, preventing, by the dam 49, the first connection metal 8 from expanding laterally too much towards the second base material 16 to be short-circuited with the second connection metal 17.

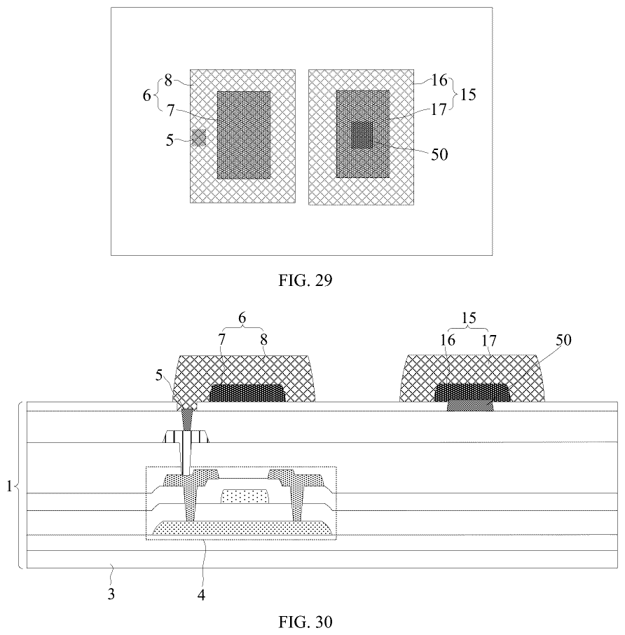

In order to make the dam 49 more effectively block the growth of the metal and prevent the metal from still covering the dam 49 and continuing to expand outward, the height design size of the dam 29 can be increased to be greater than the growth thickness of the metal. Referring again to FIG. 29, the height of the dam 49 is greater than the height of the first connection metal 8 in a direction perpendicular to the plane of the substrate 3.

In an embodiment of the present disclosure, referring to FIG. 6 again, at least a portion of the first connection metal 8 includes a first metal sub-layer 9 at least partially located on a surface of the first electrode 5 away from the substrate 3, and a second metal sub-layer 10 that covers the first metal sub-layer 9. The first electrode 5 at least overlaps the first metal sub-layer 9 in a direction perpendicular to the plane of the substrate 3.

As described above, the first metal sub-layer 9 may be a nickel-phosphorus alloy plating layer, and the second metal sub-layer 10 may be a gold plating layer. The thickness of the first metal sub-layer 9 is usually much larger than the thickness of the second metal sub-layer 10. Since the first metal sub-layer 9 is more close to the first base material 7, the first electrode 5 at least overlaps the first metal sub-layer 9, which means that the first electrode 5 is more close to the first base material 7, resulting in lower requirement for the growth thickness of the metal without excessively thick metal growth.

In one structure, the first connection structure 2 may include a redundant first connection structure, and the redundant first connection structure may be configured to test before the display panel leaves the factory, or may be configured to connect a standby light-emitting device. When the redundant first connection structure serves as a test, the redundant first connection structure continues to remain in the display panel and is no longer connected to other structures after the test ends. When the redundant first connection structure is configured to bind the standby light-emitting device and detected that a certain light-emitting device 14 is damaged and cannot emit light, the standby light-emitting device can be reconnected to the redundant first connection structure beside the certain light-emitting device 14, while the redundant first connection structure beside the light-emitting device 14 capable of emitting light normally does not need to reconnect the standby light-emitting device. The redundant first connection structure may have been connected to the pixel circuit 11 before detection, or may be connected to the pixel circuit 11 when detected that the standby light-emitting device needs to be bound thereon.

FIG. 28 is a structural schematic diagram of a display panel according to another embodiment of the present disclosure. In an embodiment of the present disclosure, as shown in FIG. 28, the driving backplane 1 includes a second electrode 50 configured to transmit a negative power signal. The connection structure 2 further includes a second connection portion 15, and at least a portion of the second connection portion 15 is configured to be connected to the negative electrode n of the light-emitting device 14. The second connection portion 15 includes a second base material 16 and a second connection metal 17. The second base material 16 is located on a surface of the second electrode 50 away from the substrate 3 and is in contact with the second electrode 50. The second connection metal 17 is at least partially located on a surface of the second base material 16 away from the substrate 3.

FIG. 29 is a top view of the display panel according to another embodiment of the present disclosure. In an embodiment of the present disclosure, referring to FIG. 28 and FIG. 29, in order to reduce the cathode contact resistance and the voltage drop of the negative power signal, the contact area between the second base material 16 and the second electrode 50 may be set to be larger than the surface area of the side of the first electrode 5 away from the substrate 3.

In other embodiments, the contact area between the second connection metal 17 and the second electrode 50 may be smaller than or equal to the surface area of the side of the first electrode 5 away from the substrate 3.

In an embodiment of the present disclosure, referring to FIG. 28 and FIG. 29, the second base material 16 covers the second electrode 50, and there is a gap between an orthographic projection of an edge of the second base material 16 on the substrate 3 and an orthographic projection of an edge of the second electrode 50 on the substrate 3, avoiding contamination or corrosion caused by an etching solution contacting the second electrode 50 when the second base material 16 is formed by etching.

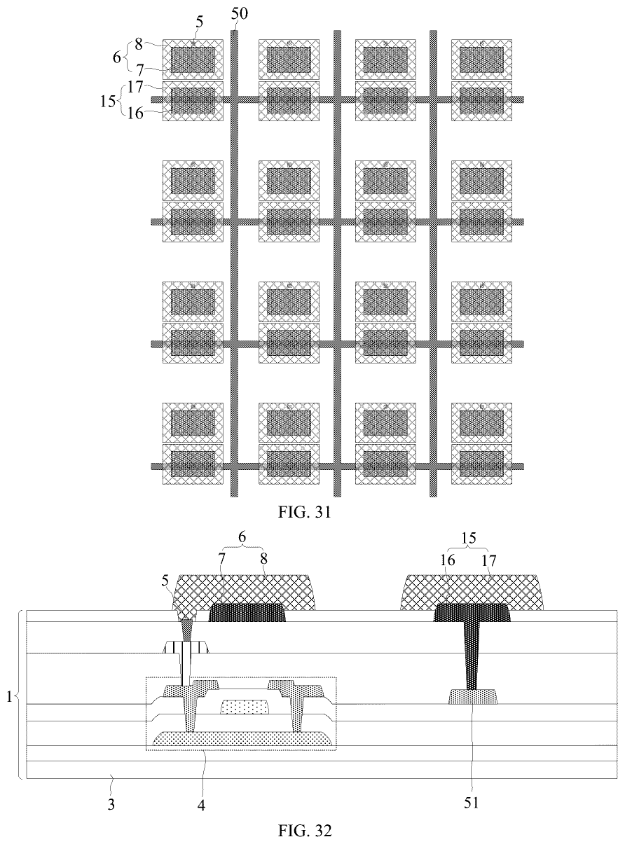

In an embodiment of the present disclosure, referring to FIG. 28 again, the driving backplane 1 further includes a power supply line 51 configured to provide a negative power signal, and the second electrode 50 is electrically connected to the power supply line 51. FIG. 30 is a structural schematic diagram of a display panel according to another embodiment of the present disclosure, and FIG. 31 is a top view of a display panel according to another embodiment of the present disclosure. In an embodiment of the present disclosure, as shown in FIG. 30 and FIG. 31, the second electrode 50 is in a grid shape, and the second electrode 50 can be reused as a power supply line at this time, thereby omitting a layer structure of the power supply line. Moreover, compared with a transmission manner in which a negative power signal is transmitted to the second electrode 50 through the power supply line 51 and then to the second connection portion 15, the second electrode 50 multiplexes the power supply line, and the negative power signal only needs to be directly transmitted from the second electrode 50 to the second connection portion 15, thereby reducing a voltage drop of the negative power signal during transmission.

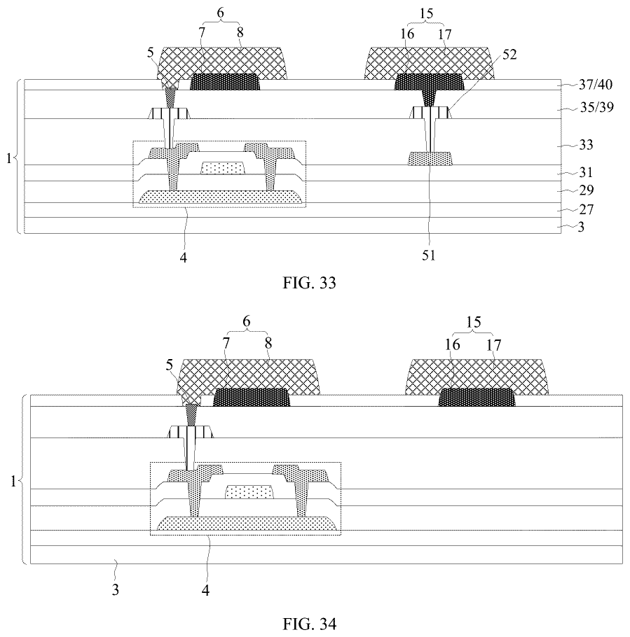

FIG. 32 is a structural schematic diagram of a display panel according to another embodiment of the present disclosure, and FIG. 33 is a structural schematic diagram of a display panel according to another embodiment of the present disclosure. In an embodiment of the present disclosure, as shown in FIG. 32 and FIG. 33, the connection structure 2 further includes a second connection portion 15, and the second connection portion 15 includes a second base material 16 and a second connection metal 17. The second connection metal 17 is at least provided on a surface of the second base material 16 away from the substrate 3.

Referring to FIG. 32, the driving backplane 1 further includes a power supply line 51, and the second base material 16 is electrically connected to the power supply line 51 through a via hole. In an embodiment of the present disclosure, referring to FIG. 33, the second base material 16 is electrically connected to the power supply line 51 through the auxiliary connection portion 52, and the auxiliary connection portion 52 is located between the second base material 16 and the power supply line 51 and is separated from the second base material 16 by an insulation layer, such as a second planarization layer 35 (a first insulation layer 39).

The second base material 16 under this structure can be reused as the second electrode 50, so that the layer structure of the second electrode 50 is omitted, and the negative power signal in the power supply line 51 is not required to be transmitted to the second base material 16 through the second electrode 50, thereby reducing the voltage drop of the negative power signal during transmission.

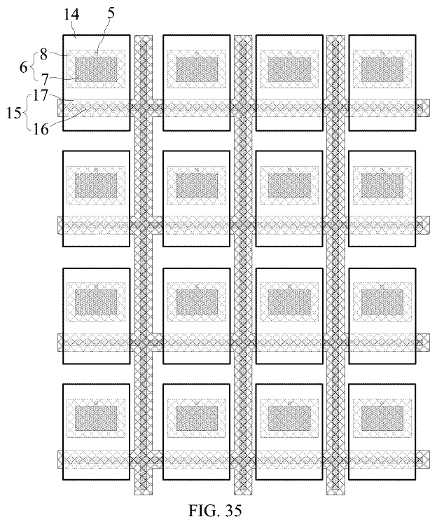

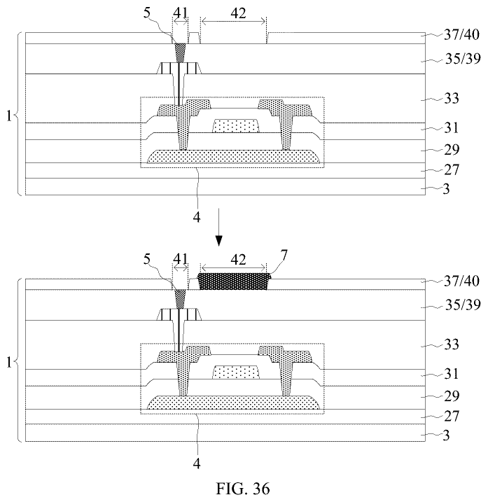

FIG. 34 is a structural schematic diagram of a display panel according to another embodiment of the present disclosure, and FIG. 35 is a top view of a display panel according to another embodiment of the present disclosure. In an embodiment of the present disclosure, as shown in FIG. 34 and FIG. 35, the connection structure 2 further includes a second connection portion 15, and the second connection portion 15 includes a second base material 16 and a second connection metal 17 that is at least partially located on a surface of the second base material 16 away from the substrate 3. The second base materials 16 in multiple second connection portions 15 communicate with one another to form a grid shape.

In such a structure, the grid shape structure formed by the multiple second base materials 16 communicating with one another can be directly reused as a power supply line, not only omitting the two layer structures of the second electrode 50 and the power supply line 51 in the driving backplane 1, but also simplifying the process and structure design to a greater extent. Moreover, the negative power signal can be directly transmitted from the grid shape structure to the light-emitting device 14 without being transmitted layer by layer by the power supply line 51 and the second electrode 50, thereby greatly reducing the signal voltage drop.

It should be noted that when the multiple second base materials 16 communicate with one another to form a grid shape structure, the connection metal formed in the chemical plating process is a grid shape, that is, the multiple second connection metals 17 communicate with one another. However, since the negative power signals received by different light-emitting devices 14 are the same, the normal display is not be affected.

Based on the same inventive concept, an embodiment of the present disclosure further provides a manufacturing method of a display panel, which is configured to manufacture the above display panel.

Referring to FIG. 4, the manufacturing method includes forming a driving backplane 1 and a connection structure 2. The driving backplane 1 includes a substrate 3, a functional circuit 4 and a first electrode 5 electrically connected to the functional circuit 4. The connection structure 2 is located at a side of the driving backplane 1, and the connection structure 2 includes a first connection portion 6.

Forming the first connection portion 6 includes: a first base material 7 is formed. The first base material 7 is not in contact with the first electrode 5. A first connection metal 8 is formed at a surface of the first base material 7 by using a chemical plating process. The first connection metal 8 is electrically connected to the first electrode 5.

In combination with the analysis above, the first base material 7 and the first electrode 5 formed by using the manufacturing process are not in contact with each other, and the first base material 7 and the functional circuit 4 are in a disconnection state. The first base material 7 is an island electrode at this time, effectively increasing the specific surface area of the first base material 7. Therefore, when forming the first connection metal 8, electrons generated by catalytic self-decomposition of the chemical plating solution on the surface of the first base material 7 cannot be adsorbed by the first base material 7 to migrate into the functional circuit, allowing the chemical plating solution to normally reduce metal on the surface of the first base material 7 to form stable first connection metal 8, thereby avoiding skip plating of the first base material 7.

In an embodiment of the present disclosure, referring to FIG. 36 and FIG. 37, the driving backplane 1 includes a first insulation layer 39 provided at a side of the functional circuit 4 away from the substrate 3, and a second insulation layer 40 provided at a side of the first insulation layer 39 away from the substrate 3, and the first electrode 5 penetrates through the first insulation layer 39.

FIG. 36 is a process flow diagram of a display panel according to an embodiment of the present disclosure. As shown in FIG. 36, a process of forming the second insulation layer 40 and the first base material 7 includes: a second insulation layer 40 is formed. The second insulation layer 40 has a first aperture 41 and a second aperture 42, and the first aperture 41 exposes the first electrode 5. A first base material 7 is formed. The first base material 7 covers the second aperture 42, and a portion of the first base material 7 is located at a side of the second insulation layer 40 away from the substrate 3.

FIG. 37 is a process flow diagram of a display panel according to another embodiment of the present disclosure. In an embodiment of the present disclosure, as shown in FIG. 37, a process of forming the second insulation layer 40 and the first base material 7 includes: a second insulation layer 40 is formed, and the second insulation layer 40 has a first aperture 41 exposing the first electrode 5. A first base material 7 is formed at a side of the second insulation layer 40 away from the substrate 3.

In this way, the first base material 7 is formed later than the second insulation layer 40, so that there is no residual insulation material on the surface of the formed first base material 7, thereby facilitating the subsequent growth of the connection metal on the surface of the first base material 7. In addition, no gap is left between the first base material 7 and the second insulation layer 40 under this structure. When growing metal by using the plating solution, the plating solution can be prevented from penetrating into the driving backplane 1 through the second insulation layer 40.

In an embodiment of the present disclosure, referring to FIG. 38, the driving backplane 1 includes a first insulation layer 39 provided at a side of the functional circuit 4 away from the substrate 3, and a second insulation layer 40 provided at a side of the first insulation layer 39 away from the substrate 3, and the first electrode 5 penetrates through the first insulation layer 39.

FIG. 38 is a process flow diagram of a display panel according to another embodiment of the present disclosure. As shown in FIG. 38, a process of forming the second insulation layer 40 and the first base material 7 includes: a first base material 7 is formed, and a second insulation layer 40 is formed. The second insulation layer 40 has a first aperture 41 and a second aperture 42. The first aperture 41 exposes the first electrode 5, and the second aperture 42 exposes a portion of the first base material 7. The second insulation layer 40 is partially located at a side of the first base material 7 away from the substrate 3.

In this manner, the first base material 7 is formed earlier than the second insulation layer 40, and there is no gap between the first base material 7 and the second insulation layer 40 in this structure. When growing the metal by using the plating solution, the plating solution can be prevented from infiltrating into the interior of the driving backplane 1.

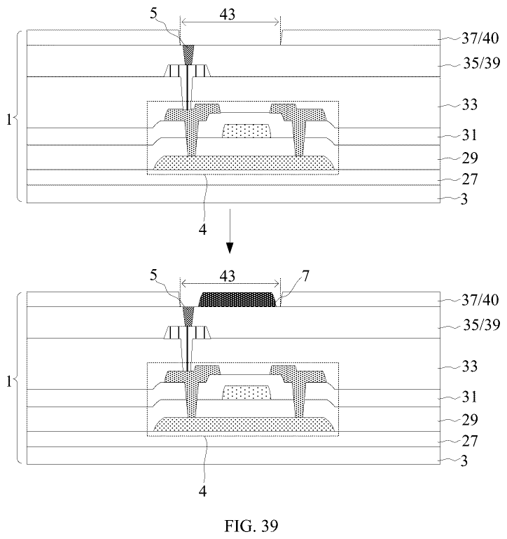

In an embodiment of the present disclosure, referring to FIG. 39 to FIG. 41, the driving backplane 1 includes a first insulation layer 39 provided at a side of the functional circuit 4 away from the substrate 3, and a second insulation layer 40 provided at a side of the first insulation layer 39 away from the substrate 3, and the first electrode 5 penetrates through the first insulation layer 39.

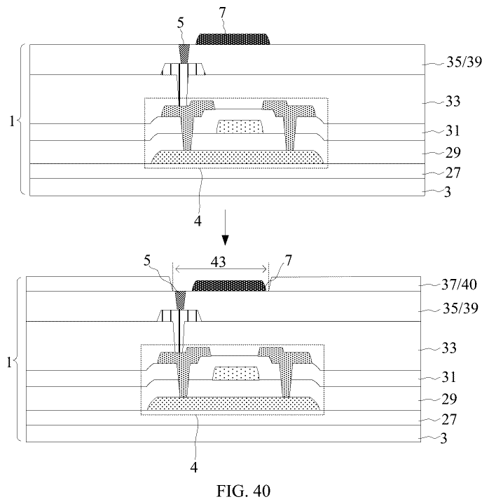

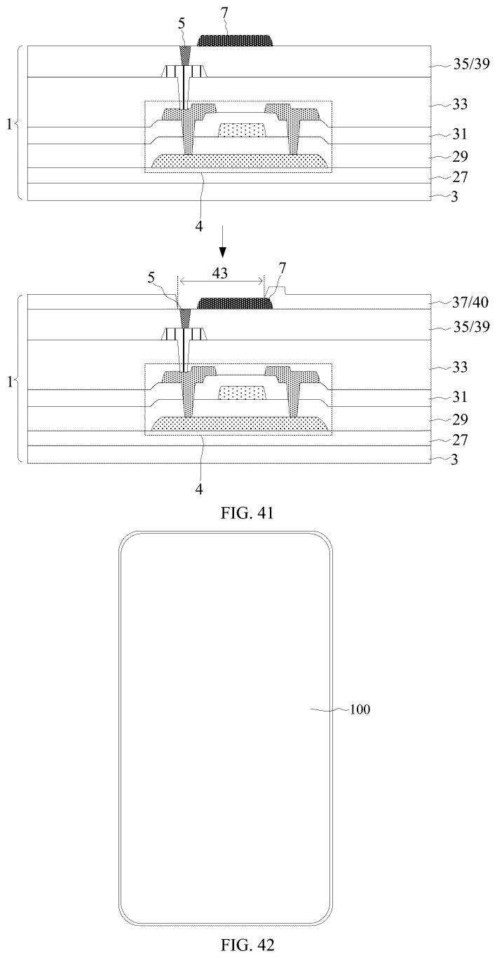

FIG. 39 is a process flow diagram of a display panel according to another embodiment of the present disclosure, FIG. 40 is a process flow diagram of a display panel according to another embodiment of the present disclosure, and FIG. 41 is a process flow diagram of a display panel according to another embodiment of the present disclosure. As shown in FIG. 39 to FIG. 41, a first base material 7 and a second insulation layer 40 are formed. The second insulation layer 40 includes a third aperture 43 exposing a first electrode 5 and simultaneously exposing at least a portion of the first base material 7 adjacent to the first electrode 5.

In an embodiment, when the third aperture 43 exposes all of the first base material 7, as shown in FIG. 39, the first base material 7 is formed first, and then the second insulation layer 40 is formed. In an embodiment of the present disclosure, as shown in FIG. 40, the second insulation layer 40 is formed first, and then the first base material 7 is formed. When the third aperture 43 exposes a portion of the first base material 7, as shown in FIG. 41, the first base material 7 is formed first, and then the second insulation layer 40 is formed.

In this structure, the third aperture 43 in the second insulation layer 40 has a large area, which can completely expose the side of the first base material 7 adjacent to the first electrode 5. The second insulation layer 40 will not affect the lateral expansion growth metal on the side of the first base material 7, thereby ensuring that the first connection metal 8 can be electrically connected to the first electrode 5.

Based on the same concept, an embodiment of the present disclosure further provides a display apparatus. FIG. 42 is a structural schematic diagram of a display apparatus according to an embodiment of the present disclosure. As shown in FIG. 42, the display apparatus includes the above display panel 100. The structure of the display panel 100 has been described in detail in the foregoing embodiments, and details are not described herein again. It is noted that the display apparatus shown in FIG. 42 is merely illustrative, and the display apparatus may be any electronic device having a display function such as a mobile phone, a tablet computer, a laptop computer, an e-book, and a television.

The above are merely exemplary embodiments of the present disclosure, which, as mentioned above, are not used to limit the present disclosure. Whatever within the principles 5 of the present disclosure, including any modification, equivalent substitution, improvement, etc., shall fall into the protection scope of the present disclosure.

Finally, it should be noted that the technical solutions of the present disclosure are illustrated by the above embodiments, but not intended to limit thereto. Although the present disclosure has been described in detail with reference to the foregoing embodiments, those skilled in the art can understand that the present disclosure is not limited to the specific embodiments described herein, and can make various modifications, readjustments, and substitutions without departing from the scope of the present disclosure.

What is claimed is:

1. A display panel, comprising:
a driving backplane comprising a substrate, a functional circuit and a first electrode electrically connected to the functional circuit; and
a connection structure provided at a side of the driving backplane and comprising a first connection portion, wherein
the first connection portion comprises a first base material and a first connection metal, and wherein the first base material is not in contact with the first electrode, the first connection metal is at least partially located on a surface of the first base material away from the substrate, and the first connection metal is electrically connected to the first electrode.

2. The display panel according to claim 1, wherein
the functional circuit comprises a pixel circuit, and the first electrode comprises a first sub-electrode electrically connected to the pixel circuit; and
the first connection portion comprises a type-I connection portion electrically connected to a light-emitting device, in the type-I connection portion, the first base material is not in contact with the first sub-electrode, and the first connection metal is electrically connected to the first sub-electrode.

3. The display panel according to claim 2, wherein:
the connection structure further comprises a second connection portion, at least a portion of the second connection portion is electrically connected to the light-emitting device, the second connection portion comprises a second base material and a second connection metal, and the second connection metal is at least located on a surface of the second base material away from the substrate; and
for the type-I connection portion, the second connection portion, and the first sub-electrode that are electrically connected to a same light-emitting device, the first sub-electrode is located at a side of the first base material in the type-I connection portion away from the second connection portion.

4. The display panel according to claim 1, wherein
the functional circuit comprises a first circuit, the first electrode comprises a pin electrode electrically connected to the first circuit through a first signal line; and
the first connection portion comprises a type-II connection portion, in the type-II connection portion, the first base material is not in contact with the pin electrode, and the first connection metal is electrically connected to the pin electrode.

5. The display panel according to claim 1, wherein
at least a portion of the first electrode is exposed to the driving backplane, and the first connection metal is in contact with the exposed portion of the first electrode; or
the display panel further comprises a protective base material, wherein the protective base material and the first base material are in a same layer and spaced apart from each other, and at least a portion of the first electrode is exposed to the driving backplane, the protective base material covers and is in contact with the exposed portion of the first electrode, and the protective base material is further electrically connected to the first connection metal.

6. The display panel according to claim 5, wherein
a distance between a surface of a side of the first connection metal away from the substrate and the surface of a side of the first base material away from the substrate is defined as d1, and a distance between the protective base material and the first base material is smaller than 2×d1.

7. The display panel according to claim 1, wherein
a gap is formed between an orthographic projection of the first base material on the substrate and an orthographic projection of the first electrode on the substrate.

8. The display panel according to claim 7, wherein
a distance between a surface of a side of the first connection metal away from the substrate and the surface of a side of the first base material away from the substrate is defined as d1, and a distance between the orthographic projection of the first base material on the substrate and the orthographic projection of the first electrode on the substrate is smaller than d1.

9. The display panel according to claim 7, wherein
the driving backplane comprises a first insulation layer provided at a side of the functional circuit away from the substrate, and a second insulation layer provided at a side of the first insulation layer away from the substrate, the first electrode penetrates through the first insulation layer, and the second insulation layer comprises a first aperture exposing the first electrode, and wherein the second insulation layer further comprises a second aperture, and the first base material is at least partially located at the second aperture, or the first base material is located at a side of the second insulation layer away from the substrate; or
the driving backplane comprises a first insulation layer provided at a side of the functional circuit away from the substrate, and a second insulation layer provided at a side of the first insulation layer away from the substrate, and the first electrode penetrates through the first insulation layer, and the second insulation layer comprises third apertures, wherein one of the third apertures exposes one of first electrodes and simultaneously exposes at least a portion of the first base material adjacent to the first electrode.

10. The display panel according to claim 7, wherein
the connection structure further comprises a second connection portion, the second connection portion comprises a second base material and a second connection metal, and the second connection metal is at least partially located on a surface of the second base material away from the substrate; and
wherein a lower surface of the first base material facing the substrate and a lower surface of the second base material facing the substrate are in contact with a same insulation layer in the driving backplane.

11. The display panel according to claim 1, wherein
the first electrode comprises at least two sub-portions, and the at least two sub-portions are located at different sides of the first base material, respectively;
wherein the at least two sub-portions comprise a first sub-portion and a second sub-portion;
wherein the first sub-portion has a first size along an arrangement direction of the first sub-portion and the first base material, the second sub-portion has a second size along an arrangement direction of the second sub-portion and the first base material, and the first size is greater than the second size; and/or
a first distance between an orthographic projection of the first sub-portion on the substrate and an orthographic projection of the first base material on the substrate is greater than a second distance between an orthographic projection of the second sub-portion on the substrate and the orthographic projection of the first base material on the substrate.

12. The display panel according to claim 1, wherein
an orthographic projection of the first electrode on the substrate at least partially surrounds an orthographic projection of the first base material on the substrate; or
a distance between an upper surface of a side of the first electrode away from the substrate and the substrate is greater than a distance between an upper surface of a side of the first base material away from the substrate and the substrate.

13. The display panel according to claim 1, further comprising a dam, wherein the dam and the first electrode are located at different sides of the first base material, respectively.

14. The display panel according to claim 1, wherein
at least a portion of the first connection metal comprises a first metal sub-layer at least partially provided at a surface of the first electrode away from the substrate, and a second metal sub-layer that covers the first metal sub-layer, and the first electrode at least overlaps the first metal sub-layer in a direction perpendicular to a plane of the substrate.

15. The display panel according to claim 1, wherein
the driving backplane further comprises a second electrode; and
the connection structure further comprises a second connection portion, and the second connection portion comprises a second base material provided at a surface of a side of the second electrode away from the substrate, and a second connection metal at least partially provided at a surface of the second base material away from the substrate.

16. The display panel according to claim 15, wherein
a contact area between the second base material and the second electrode is greater than an area of a surface of a side of the first electrode away from the substrate; or
the second base material covers the second electrode, and a gap is formed between an orthographic projection of an edge of the second base material on the substrate and an orthographic projection of an edge of the second electrode on the substrate.

17. The display panel according to claim 1, wherein
the connection structure further comprises a second connection portion comprising a second base material and a second connection metal at least provided at a surface of the second base material away from the substrate; and
the driving backplane further comprises a power supply line, the second base material is electrically connected to the power supply line through a via hole, or the second base material is electrically connected to the power supply line through an auxiliary connection portion, the connection portion is located between the second base material and the power supply line, and an insulation layer is located between the connection portion and the second base material.

18. The display panel according to claim 1, wherein
the connection structure further comprises a plurality of second connection portions, one of the plurality of second connection portion comprises a second base material and a second connection metal, and the second connection metal is at least partially located on a surface of the second base material away from the substrate; and
the second base materials of the plurality of second connection portions communicate with one another to form a grid shape.

19. A method for manufacturing a display panel according to claim 1, wherein the display panel comprises:
a driving backplane comprising a substrate, a functional circuit and a first electrode electrically connected to the functional circuit; and
a connection structure provided at a side of the driving backplane and comprising a first connection portion, wherein
the first connection portion comprises a first base material and a first connection metal, and wherein the first base material is not in contact with the first electrode, the first connection metal is at least partially located on a surface of the first base material away from the substrate, and the first connection metal is electrically connected to the first electrode;
the method comprises:
forming a driving backplane and a connection structure, wherein the driving backplane comprises a substrate, a functional circuit and a first electrode electrically connected to the functional circuit; the connection structure is located at a side of the driving backplane and comprises a first connection portion; and
wherein forming the first connection portion comprises: forming a first base material, wherein the first base material is not in contact with the first electrode; and forming a first connection metal on a surface of the first base material by using a chemical plating process, wherein the first connection metal is electrically connected to the first electrode.

20. A display apparatus, comprising a display panel, the display panel, comprising:
a driving backplane comprising a substrate, a functional circuit and a first electrode electrically connected to the functional circuit; and
a connection structure provided at a side of the driving backplane, wherein the connection structure comprises a first connection portion, the first connection portion comprises a first base material and a first connection metal, and wherein the first base material is not in contact with the first electrode, the first connection metal is at least partially located on a surface of the first base material away from the substrate, and the first connection metal is electrically connected to the first electrode.
